(19) United States
(12) Patent Application Publication
(10) Pub. No.: US 2019/0043701 A1
(43) Pub. Date: Feb. 7, 2019

(54) INVERTED MAGNETRON FOR PROCESSING OF THIN FILM MATERIALS

(71) Applicant: HIA, Inc., Livermore, CA (US)

(72) Inventors: Samuel D. Harkness, IV, Albany, CA (US); Quang N. Tran, San Jose, CA (US)

(73) Assignee: HIA, Inc., Livermore, CA (US)

(21) Appl. No.: 16/050,504

(22) Filed: Jul. 31, 2018

Related U.S. Application Data
(60) Provisional application No. 62/540,473, filed on Aug. 2, 2017.

(51) Int. Cl. H01J 37/34; C23C 14/35; C23C 14/34

(52) U.S. Cl. CPC H01J 37/3408; C23C 14/354; C23C 14/3407; C23C 14/351

(57) ABSTRACT

A magnet pack has a permeable assembly with a first cutout for a center magnet and second cutouts for peripheral magnets surrounding the center magnet. A target is attached to the permeable assembly. A heatsink is attached to the target. Emanating magnetic fields from the magnet pack progress from an inner atmospheric side to a position substantially within a vacuum cavity. The emanating magnetic fields from the center magnet are substantially stronger than the emanating magnetic fields from the peripheral magnets.

### CROSS-REFERENCE TO RELATED APPLICATION

This application claims priority to U.S. Provisional Patent Application 62/540,473, filed Aug. 2, 2017, the contents of which are incorporated herein by reference.

### FIELD OF THE INVENTION

This invention relates generally to material processing. More particularly, this invention is directed toward an inverted magnetron for processing of thin film materials.

### BACKGROUND OF THE INVENTION

Ceramic thin films have been produced by reactively sputtering metallic targets with a mix of inert working gas and reaction species (e.g., N₂, O₂, CH₂, etc.) in a process known as ‘transition mode’. Transition mode refers to the space within which stable processing without resultant target poisoning is possible. Target poisoning occurs as the metallic target material is rendered increasingly non-conductive through action of the reactant gas species creating insulating films with diminishing secondary electron generation and lower sputter yield. Although effective, the process is limited in terms of film quality capability as a certain fraction of un-reacted metallic species is certain to join the adsorbate resulting in increased film pinhole density, worse control of resistivity, and lower optical transparency (free carrier adsorption in the red-infrared region). Also, the deposition rate is limited and is generally lower than deposition via competing technologies, such as plasma enhanced chemical vapor deposition (PECVD). Additionally, owing to the fact that traditional sputter is neutral and adsorbate species are scattered to all locations within line of sight of the cathode, build-up of high stress material and ultimate delamination raises the observed particulate level during processing.

It would be advantageous to operate with only the reactant gas species used as the sputter working gas, but for the reasons aforementioned, this leads to target poisoning and is therefore not sustainable. In fact, when the partial pressure of reactant gas rises, the target consumes the reactant gas species through a combination of implantation and chemisorption phenomena, which yields a non-linear response of measured pressure to reactant gas flow. After the target is poisoned, and the reactant flow is systematically reduced, a hysteresis response in pressure is observed as the reactant partial now acts linearly with flow due to a lack of continued consumption.

The key is to sustain erosion while maintaining the conductivity and sputter yield of the cathode material. A complicating factor is the loss of anode due to accumulation of insulating film during processing. This causes an increase in plasma impedance and accelerates the poisoning process.

Another concern related to reactive sputtering is the fact that while the reactant gas is ionized, the adsorbate comprising sputter ejected species is largely neutral and therefore less reactive leading to a higher fraction of free metal species in the resulting film.

As mentioned above, another popular technique for the fabrication of insulating thin films is PECVD. Using this methodology, film designers are able to readily produce nearly stoichiometric film compositions at acceptable deposition rates, low defectivity, film stress and requiring of moderate to low substrate temperature (to facilitate chemical reaction). However, there are defined issues arising in the form of scalability and film uniformity. Moreover, the need for complicated radio-frequency hardware is costly and not easily implemented in an in-line or pass-by deposition arrangement.

It is beneficial to have a steeper magnetic field gradient of flux passing through a sputtering target cathode material such that a larger volume of plasma confinement may be achieved. This may be accomplished by separating the magnetic poles to inhibit the flux from being drawn laterally to the opposite polarity pole directly. Unfortunately, as the opposing poles are separated in space, the flux gradient becomes increasingly divergent as the flux emanating from individual poles becomes returned symmetrically with respect to the pole centroid. With magnetic flux divergent from a given pole that is not ultimately captured by a pole of opposing polarity, there is reduced capability for electron confinement. It is this confinement that is responsible for the useful operation of a sputter magnetron at low operating pressures (<10 mTorr). However, if it were possible to maintain confinement while separating the two poles to a maximum distance, the plasma ionization volume above the target could be increased drastically.

### SUMMARY OF THE INVENTION

A magnet pack has a permeable assembly with a first cutout for a center magnet and second cutouts for peripheral magnets surrounding the center magnet. A target is attached to the permeable assembly. A heatsink is attached to the target. Emanating magnetic fields from the magnet pack progress from an inner atmospheric side to a position substantially within a vacuum cavity. The emanating magnetic fields from the center magnet are substantially stronger than the emanating magnetic fields from the peripheral magnets.

### BRIEF DESCRIPTION OF THE FIGURES

The invention is more fully appreciated in connection with the following detailed description taken in conjunction with the accompanying drawings, in which:

FIG. 1 illustrates a cylindrical magnetron assembly and its magnetic flux lines relative to a substrate.

FIG. 2a is a top view of a magnet pack configured in accordance with an embodiment of the invention.

FIG. 2b is a cross-section schematic view of the magnet pack of FIG. 2a.

FIG. 3a is a side view of a cylindrical magnetron configured in accordance with an embodiment of the invention.

FIG. 3b is a side view of a cylindrical magnetron and associated flux lines formed in accordance with an embodiment of the invention.

FIG. 3c illustrates an offset inner magnet array utilized in accordance with an embodiment of the invention.

Like reference numerals refer to corresponding parts throughout the several views of the drawings.

### DETAILED DESCRIPTION OF THE INVENTION

A novel hardware solution offers new capability in the realm of thin film processing in the physical vapor deposition mode (PVD). Apparatus is described that enables a large separation between opposing polarity magnet arrays such that a commensurately larger plasma volume above a cathode target is created. In this way, a wider parameter space in processing is now accessible especially in the application of PVD via cylindrical magnetron.

A magnetic pole configuration is disclosed. The magnetic pole configuration may be used in any number of magnetron designs. In one embodiment, the pole structure is mounted within either a planar or cylindrical cathode structure. The device is used for effective deposition of material upon a chosen substrate. Ancillary systems, such as power, cooling, and shielding may be implemented in any number of ways.

Generally, a cathode assembly is prepared for operation in a vacuum environment (P<1 Torr), which is commonly evacuated below 1×10⁻⁵ Torr to effect the minimization of film contamination due to incorporation of background species (e.g., H, C, O, N, and the multitude of molecular combinations therein). Without the accompaniment of an appropriate magnet pack situated behind the cathode assembly, the physics of operation require high working gas pressure (e.g., Ar) to ensure avalanche style impact ionization of the gas, which may then be used to sputter the target material. When used in conjunction with a magnet pack that sufficiently confines electron flux, the cathode is able to be operated at lower working pressures (1-10 mTorr) and results in higher deposition rate and less entrainment of background gas species within the film structure.

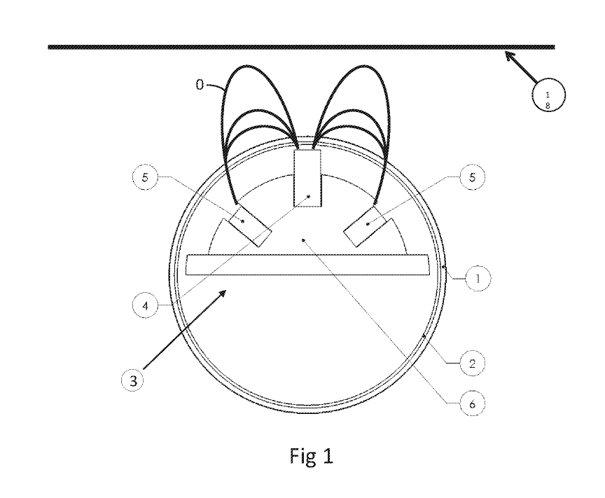

FIG. 1 illustrates a magnet pack 3 with a first magnet (center pole) 4 positioned centrally between second magnetic array 5. The first magnet 4 and second magnetic array 5 are formed within a permeable assembly 6 with cutouts to accommodate the magnets. A cylindrical target 1 is affixed to a heatsink 2. The field polarity is parallel at all points confined by the outer edge of the top and bottom surface of this array. A parallel field from array 4 is nearly perpendicular to the cathode surface 1. FIG. 1 also illustrates field lines 0 proximate to substrate 18.

The magnet pack 3 is constructed with a magnet pack host assembly 6 made with permeable material (μ/μ₀>10, more preferably ˜1000) designed to hold the magnet array(s) in place. This assembly 6 has the additional benefit of directing the emanating magnetic field lines 0 in a vector desired by the designer. The degree to which the permeable assembly 6 is produced with cavities for the magnet arrays 4,5 has a large effect on the field strength observed above the target 1 surface. Moreover, as a matter of field management, the shape of the cavity or cavities surrounding the magnet array(s) may enable control of flux density in localized regions. This phenomenology is useful in many ways, not the least of which is the ability to control the amount of erosion occurring at the end portion of a cylindrical magnetron target. This ability allows the magnetron user to ensure that the highest target utilization (i.e., erosion depth) occurs in that portion of the target from which the majority of film collected on the intended substrate is derived from.

The permeable assembly 6 contains additional cavity cutouts that flank the cutout containing magnetic array 4 as shown as being occupied by a second magnet array 5. These cavities serve as a guide for the return magnetic field that originated at the top surface of the center array 4. It is this convergence of field at these cavity locations that serves functionally as the reverse polarity pole and provides an edge to the plasma confinement zone provided there is enough measurable flux (>200 Gauss).

FIG. 1 shows the flux lines connecting the center pole array 4 to the flanking cavity locations. The magnet array is flanked optionally by a second magnetic structure 5 where the magnetic strength of the first array 4 is at least 150% the strength (measured in absolute value) of the second array 5 when associated fields are measured at an equidistant position above the top of each array (e.g., directly above the cathode target). The first magnet array 4 is of sufficient magnetic strength to pass flux through a myriad of magnetic and non-magnetic target materials 1 and is therefore comprised of magnets with strengths between (20 MGOe and 52 MGOe) and more preferably 45 MGOe. The second magnet array 5 is of magnetic strength less than 52 MGOe and may be adjusted to fulfill the abovementioned strength relationship with respect to the first array 4. Another approach to modulating the relative flux strengths of one array versus the other is to engineer the position of the top magnet surface relative to the target surface independently. Therein, a large combination exists of selected magnet strengths and positioning. A substrate 18 to be coated is above the active portion of the assembly.

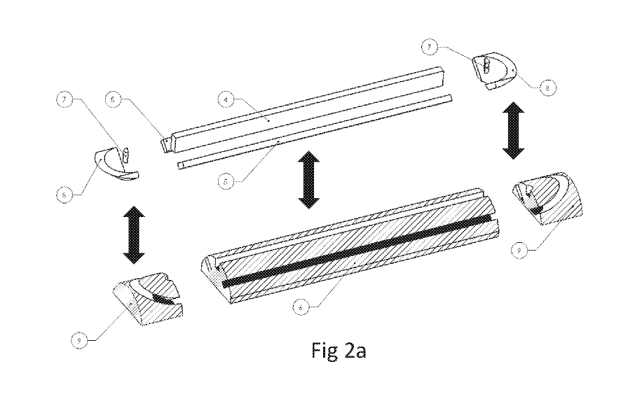

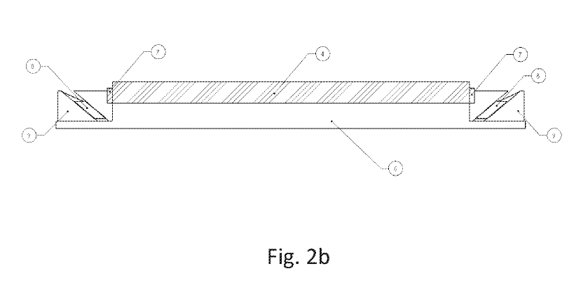

FIG. 2a illustrates relative positions of end assemblies 9 to permeable assembly 6, configured as a center rail. Magnet components 4, 5 of FIG. 1 are shown in FIG. 2a. FIG. 2a also illustrates magnets 7 and 8 in relief above the permeable bodies 6, 9. The outer magnet array 5 is connected to end cap arc rings 8 at either end. The inner array 4 is connected to end magnet pieces 7 abutting both ends.

FIG. 2b is a cross-section schematic showing permeable bodies 6, 9 and end slot angle for housing of end magnet array 8 and potential height differentials between rail magnet array 4 and end cap magnets 7. The end pieces 7 of the center rail 4 are shown as being at a lower vertical height. This highlights one adjustable feature of this magnet pack that can be used in conjunction with other adjustments to equilibrate the volumetric erosion rate across the surface of the cylinder length. Also shown in FIG. 2b are the end ring magnet arrays 8, which are positioned in the outer ring slot of the permeable body 9. As previously mentioned, the relative strength of both localized magnetic field and balance in flux emanating from both arrays is adjustable. This freedom enables control of local erosion rates and is used to reduce the over-erosion often experienced at that location where the magnet track turns in the circumferential direction to close the loop.

The disclosed structure allows larger separation between the inner and outer magnetic poles (versus a standard balanced magnetron design) thus promoting a greater volume of ionization above the target as well as a larger portion of the target surface that is subsequently eroded by the ensuing plasma. This technology is also effective when used in conjunction with a static magnetron process source.

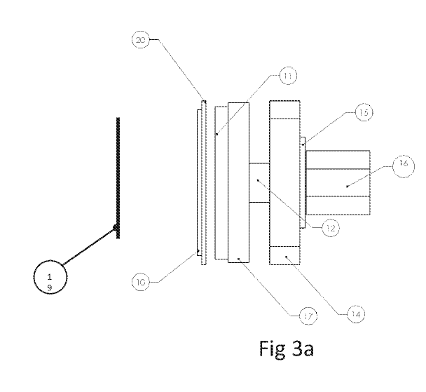

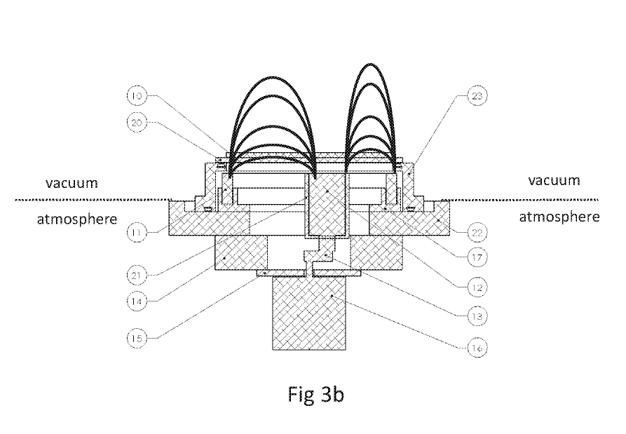

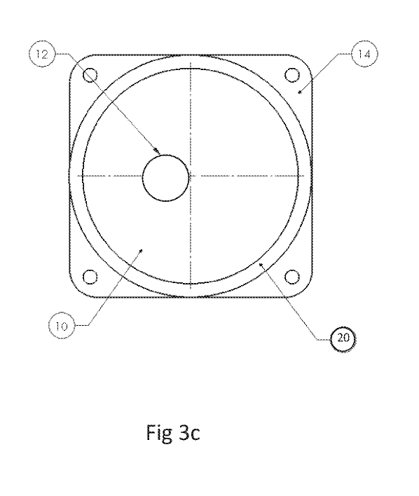

In FIG. 3a, critical components of the assembly are shown in cross-section in relation to a wafer substrate 19 to be coated. A more detailed drawing including a representation of the magnetic flux lines is shown in FIG. 3b.

A round cathode target 10 is affixed to a heatsink 20. The joined assembly sits atop a magnet pack assembly shown as an outer magnet ring 11 and a magnet keeper plate 17. The magnet ring 11 is polarized along the vertical axis and is anti-parallel to the inner magnet (or magnet ring) 12. As described for the cylindrical magnetron magnet pack art above, the inner array 12 is 150% the magnet flux of the outer array 11 (measured in absolute value) when associated fields are measured at an equidistant position above the top of each array (e.g., directly above the cathode target 10).

The inner magnet array 12 is of sufficient magnetic strength to pass flux through a myriad of magnetic and non-magnetic target materials 10 and is therefore comprised of magnets with strengths between (20 MGOe and 52 MGOe) and more preferably 45 MGOe. The outer magnet array 11 is of magnetic strength within the same range as for 12 and may be adjusted to fulfill the abovementioned strength relationship with respect to the inner array 12. The keeper plate 17 is constructed with a channel to bolster the field of the outer array in the vertical direction (perpendicular to the target 10). The keeper plate is made with permeable material (μ/μ₀>10, more preferably ˜1000).

As an unintended consequence of the inner array 12, it is observed that confinement occurs at the outer edge of the inner magnet array 12 leaving that portion of the target surface directly above the inner portion of the inner array to be un-eroded since fast electron transport into that region would be impermissible. A solution to this problem is offered in the form of offsetting the inner array 12 with respect to the target center such that the center-point is always within the electron confinement region spaced between the inner 12 and outer 11 magnet arrays. The entire inner array structure 12 is then rotated in orbit around the center-point of the target. This concept is represented schematically in FIG. 3c wherein an outline of the inner magnet array 12 is shown offset by a length of one times the radius of the inner array 12. FIG. 3c also illustrates cathode target 10, mounting flange 14 and heat sink 20.

FIG. 3b shows a drive motor 16 that is affixed to a mounting flange 14 via a bushing 15. A camshaft 13 is connected to the motor that allows the dislocation of the inner magnet array 12 with respect to the target center-point. At the end of the camshaft is attached the permeable keeper cup 21 that is used to contain the inner magnet array 12. The height of the walls of this cup 21 relative to the magnet array 12 height has a secondary effect on the emanating magnetic field gradient. Thus, it is observed to be best practice to match the wall height to the top of the inner magnet array 12.

In order to facilitate uniform erosion of the target surface as a result of the dislocation of the inner magnet array 12, the motor rotates the assembly at approximately 600 revolutions per minute (RPM). This ensures that the piece being coated will experience 10 full rotations of the magnet array 12.

Lastly, in support of vacuum processing, a mounting flange 22 is used to attach the motor flange 14 and the outer magnet array holder plate 17 on the atmospheric side, and the cathode mounting assembly 23 which positions the target on the vacuum side of the flange.

In one embodiment, the magnet pack has cutout portions to house magnet arrays 4,5. The depth of the cutout is sufficient to allow independent adjustment of arrays 4,5 with respect to distance from top magnet surface 4,5 to backside of heatsink 2. The angle of the axial centerline of cutouts for array 5 are between 0 degrees and 90 degrees and more preferably 45 degrees with respect to the axial centerline of the cutout for array 4.

Optional end magnet array 7 is attached in such a way that the magnetic field polarity measured along the radial axis of cylindrical cathode is unidirectional as analyzed in the locus of points connecting the end of array 4 and array 7. Optional end arc magnet array 8 is attached in such a way that the magnetic field polarity measured along radial axis of the cylindrical cathode is unidirectional as analyzed in the locus of points connecting the end of array 5 and array 8.

Optional arc ring assemblies 9 may be attached at either end of the above-mentioned permeable assembly 6. Each arc ring assembly 9 is made of material (preferably stainless steel 410) with relative permeability, μ/μ₀>10, more preferably ˜1000. The optional assembly 9 may be produced with cutout portions (see for example, FIG. 2b) to house magnet arrays 7,8. The depth of the cutout is sufficient to allow independent adjustment of arrays 7,8 with respect to distance from top magnet surface 7,8 to backside of heatsink 2. The angle of the axial centerline of cutout for array 8 with respect to the axial centerline of the cutout for array 7 may vary between 0 degrees and 90 degrees. The angle may also change gradually within the same limits along the arc of the cutout. Preferably, the angle at the point nearest the face of assembly 9 that abuts assembly 6 is matching to the cutout angle in assembly 6.

A target 10 mounted on a heatsink 20 facilitates the deposition of material upon a static substrate (e.g., 19). An inner magnet array 12 and an outer magnet array 11 surrounds the inner array. Both arrays 11, 12 are positioned such that emanating magnetic fields progress from the inner atmospheric side of the assembly to a position substantially within the vacuum cavity surrounding the outer dimension of the cathode assembly (see for example flux lines drawn schematically in FIG. 3b).

Inner driver magnet array 12 comprises magnets with magnetic strength between 20 MGOe and 52 MGOe and more preferably 45 MGOe. Outer magnet array 5, 11 comprises magnets with magnetic strength between 20 MGOe and 52 MGOe and more preferably 45 MGOe. Magnetic flux emanating in a direction perpendicular to the plane of the target 10 and measured on the surface of the target cathode 10 directly above the inner magnet array 12 is at least 150% the flux measured on the surface of the target cathode 10 directly above the outer magnet array 11. It is preferable to operate the magnetron while the inner magnet array flux is 200-300% that of the outer array.

Each array 11,12 is contiguous and is arranged such that there is found one flux polarity reversal (i.e., that position laterally along the target cathode surface where the magnetic flux perpendicular to the surface is found to be zero, thus indicating a switch in flux polarity) between any two points connecting the inner array 12 to the outer array 11.

The magnetic flux perpendicular to the surface of the target cathode 10 and measured at the surface directly above the outer magnetic array 11 is at least 200 G and more preferably 500 G. The magnetic field polarity of the inner array 12 is parallel at all points confined within the circumference of the array (measured atop the surface of the target cathode 10).

A permeable magnet holder assembly 17 is made of material (preferably stainless steel 410) with relative permeability, μ/μ₀>10, more preferably ˜1000. The material is fabricated into a shape such that walls flank the outer magnet array 11. The walls extend from the base of the magnet 11 through to a selected height between 0% and 100% of the magnet 11 height and preferably to 50% (the midpoint of the magnet height). The assembly 17 is annular to provide open space across the interior.

The assembly 17 is attached to a vacuum mounting flange 22 on the vacuum side of the flange. The inner magnet array 12 is held by a permeable magnet holder assembly 21, which is made of material (preferably stainless steel 410) with relative permeability, μ/μ₀>10, more preferably ˜1000. The material is fabricated into a shape such that walls flank the inner magnet array 12. The walls extend from the base of the magnet 12 through to a selected height between 0% and 100% of the magnet 12 height and preferably to 100% (i.e., completely shrouding the magnet array 12).

The assembly 21 is attached to a camshaft 13 wherein the centerline of the magnet array 12 is thereby repositioned to an offset with respect to the target 10 centerline axis. The offset is engineered as per desire to a value between zero, and the radius of the outer magnet holder assembly 17 aperture minus the radius of the inner magnet holder assembly 21. Preferably, the offset is at least one times the radius of the inner magnet array 12.

A camshaft 13 is connected to a drive motor 16 capable of supplying rotation of the cam between 0 RPM, and 7,200 RPM and more preferably 600 RPM. The motor assembly 16 is attached to a bushing 15 which is attached to a motor mounting plate 14. The motor mounting plate 14 is then attached to the atmospheric side of the vacuum mounting flange 22.

The foregoing description, for purposes of explanation, used specific nomenclature to provide a thorough understanding of the invention. However, it will be apparent to one skilled in the art that specific details are not required in order to practice the invention. Thus, the foregoing descriptions of specific embodiments of the invention are presented for purposes of illustration and description. They are not intended to be exhaustive or to limit the invention to the precise forms disclosed; obviously, many modifications and variations are possible in view of the above teachings. The embodiments were chosen and described in order to best explain the principles of the invention and its practical applications, they thereby enable others skilled in the art to best utilize the invention and various embodiments with various modifications as are suited to the particular use contemplated. It is intended that the following claims and their equivalents define the scope of the invention.

1. A magnet pack, comprising:
a permeable assembly comprising a first cutout for a center magnet and second cutouts for peripheral magnets surrounding the center magnet;
a target attached to the permeable assembly; and
a heatsink attached to the target, wherein emanating magnetic fields from the magnet pack progress from an inner atmospheric side to a position substantially within a vacuum cavity, wherein the emanating magnetic fields from the center magnet are substantially stronger than the emanating magnetic fields from the peripheral magnets.

2. The magnet pack of claim 1 wherein the center magnet has a magnetic strength between 20 MGOe and 52 MGOe.

3. The magnet pack of claim 2 wherein the center magnet has a magnetic strength of approximately 45 MGOe.

4. The magnet pack of claim 1 wherein the peripheral magnets have a magnetic strength between 20 MGOe and 52 MGOe.

5. The magnet pack of claim 4 wherein the peripheral magnets have a magnetic strength of approximately 45 MGOe.

6. The magnet pack of claim 1 wherein the emanating magnetic fields from the center magnet are at least 150% stronger than the emanating magnetic fields from the peripheral magnets.

7. The magnet pack of claim 1 wherein the emanating magnetic fields from the center magnet are at least 200% stronger than the emanating magnetic fields from the peripheral magnets.

8. The magnet pack of claim 1 wherein emanating magnetic fields from the peripheral magnets are at least 100 G.

9. The magnet pack of claim 1 wherein the permeable assembly has a relative permeability of μ/μ₀>10.
